(19) United States
(12) Patent Application Publication
(10) Pub. No.: US 2015/0061093 A1
(43) Pub. Date: Mar. 5, 2015

(54) INTERPOSER AND SEMICONDUCTOR PACKAGE USING THE SAME, AND METHOD OF MANUFACTURING INTERPOSER

(71) Applicant: SAMSUNG ELECTRO-MECHANICS CO., LTD., Suwon-si (KR)

(72) Inventors: Ki Hwan KIM, Suwon-si (KR); Jung Hyun PARK, Suwon-si (KR); Yong Yoon CHO, Suwon-si (KR); Sung Won JEONG, Suwon-si (KR); Da Hee KIM, Suwon-si (KR); Gi Ho HAN, Suwon-si (KR)

(21) Appl. No.: 14/472,365

(22) Filed: Aug. 28, 2014

(30) Foreign Application Priority Data
Aug. 30, 2013 (KR) 10-2013-0104142

(51) Int. Cl. H01L 23/498; H01L 23/31; H01L 21/768

(52) U.S. Cl. CPC H01L 23/49811; H01L 21/76805; H01L 21/76877; H01L 23/49827; H01L 23/3142
USPC 257/668; 257/774; 438/666

(57) ABSTRACT

Disclosed herein is an interposer, including: an interposer substrate configured by stacking an insulating layer of one layer or more and interlayer connected through a via; a cavity penetrating through a center of the interposer substrate in a thickness direction; and a connection electrode having a post part which is disposed on at least one of an upper surface and a lower surface of the interposer substrate, thereby increasing electrical characteristics and reducing manufacturing cost and time.

This application claims the foreign priority benefit under 35 U.S.C. Section 119 of Korean Patent Application Serial No. 10-2013-0104142 entitled “Interposer And Semiconductor Package Using The Same, And Method Of Manufacturing Interposer” filed on Aug. 30, 2013, which is hereby incorporated by reference in its entirety into this application.

### BACKGROUND OF THE INVENTION

1. Technical Field

The present invention relates to an interposer, and more particularly, to an interposer and a semiconductor package using the same, and a method of manufacturing an interposer.

2. Description of the Related Art

As a demand for a small, light, and high-integrated semiconductor device is increased, a three dimensional integrated circuit, such as a stacked chip package, has been researched. Generally, the three dimensional integrated circuit includes an interposer for interconnection between semiconductor chips which are stacked to be adjacent to each other.

Describing a basic structure having a package configuration using an interposer according to the related art by referring to Patent Document (Patent Application No. 10-2009-7023266), the interposer is disposed between a substrate and a semiconductor device and includes various wirings in addition to channels (that is, vias) for transferring a plurality of signals for electrically connecting between the substrate and the semiconductor device.

Generally, the interposer is formed by stacking a plurality of insulating layers, and thus a height of the interposer may be controlled depending on the number of layers of the insulating layer. That is, when a thicker interposer is required, there is a need to stack a larger number of insulating layers.

However, in the case of controlling the height of the interposer by the method, the insulating layer is unnecessarily stacked even in a space in which there is no need to form a wiring in the interposer, thereby causing a considerable waste of material. Further, when the number of layers of the insulating layer is increased, a path of electrical signals conducted through vias and wirings formed in the insulating layers of each layer becomes long, such that a signal loss and a distortion may be increased.

Meanwhile, between the interposer and the substrate and the interposer and the semiconductor device may be connected through a bonding film, a solder paste, a solder ball, and the like. By the bonding method, a bonded portion is widely formed, such that it is difficult to control integration of a circuit.

### RELATED ART DOCUMENT

### Patent Document

(Patent Document 1) Patent Document: Patent Application No. 10-2009-7023266

### SUMMARY OF THE INVENTION

An object of the present invention is to increase electrical characteristics while more reducing manufacturing costs and time and more increasing production efficiency as compared with the related art, by providing an interposer having a connection electrode having a pillar shape and configuring a semiconductor package using the interposer.

According to an exemplary embodiment of the present invention, there is provided an interposer, including: an interposer substrate configured by stacking an insulating layer of one layer or more and interlayer connected through a via; a cavity penetrating through a center of the interposer substrate in a thickness direction; and a connection electrode having a post part which is disposed on at least one of an upper surface and a lower surface of the interposer substrate.

The connection electrode may include a pad part which is disposed between the post part and the interposer substrate.

A height of the post part may be controlled corresponding to a thickness of the semiconductor device included in the cavity.

The connection electrode may be configured in plural.

The upper surface of the post part may be further provided with a metal layer.

A surface of the connection electrode may be provided with roughness.

According to another exemplary embodiment of the present invention, there is provided a semiconductor package, including: a package substrate disposed on upper and lower portions of the interposer substrate as described above and electrically connected to the interposer substrate through the connection electrode; a semiconductor device mounted on one surface of the package substrate and included in a cavity of the interposer substrate; and a sealing material filled to seal the semiconductor device including an inside of the cavity.

According to still another exemplary embodiment of the present invention, there is provided a method of manufacturing an interposer, including: preparing an interposer substrate configured by stacking an insulating layer of one layer or more and interlayer connected through a via; stacking photo resists on one surface or both surfaces of the interposer substrate; machining an opening at a position at which a connection electrode is formed in the photo resist and then filling an inside of the opening; forming the connection electrode having a post part by delaminating the photo resist; and forming a cavity to penetrate through a center of the interposer substrate in a thickness direction.

A thickness of the photo resist may be stacked at a height corresponding to a thickness of the connection electrode.

The method of manufacturing an interposer may further include: polishing a surface of the photo resist, after the forming of the connection electrode.

The method of manufacturing an interposer may further include: prior to the forming of the connection electrode having a post part by delaminating the photo resist, forming a metal layer on an upper surface of the post part.

The method of manufacturing an interposer may further include: after the forming of the connection electrode having a post part by delaminating the photo resist, forming roughness by surface treating the connection electrode.

### BRIEF DESCRIPTION OF THE DRAWINGS

FIG. 1 is a cross-sectional view of an interposer according to an exemplary embodiment of the present invention.

FIG. 2 is a plane view of the interposer according to the exemplary embodiment of the present invention.

FIG. 3 is a cross-sectional view of a semiconductor package using the interposer according to the exemplary embodiment of the present invention.

FIGS. 4 to 10 are process diagrams sequentially illustrating a method of manufacturing an interposer according to an exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Terms used in the present specification are for explaining exemplary embodiments rather than limiting the present invention. Unless explicitly described to the contrary, a singular form includes a plural form in the present specification. Further, the word “constituents”, “steps”, “operations”, and/or “elements” mentioned herein will be understood to imply the inclusion of stated constituents, steps, operations and/or elements but not the exclusion of any other constituents, steps, operations and/or elements.

Hereinafter, a configuration and an action effect of the present invention will be described in more detail with reference to the accompanying drawings.

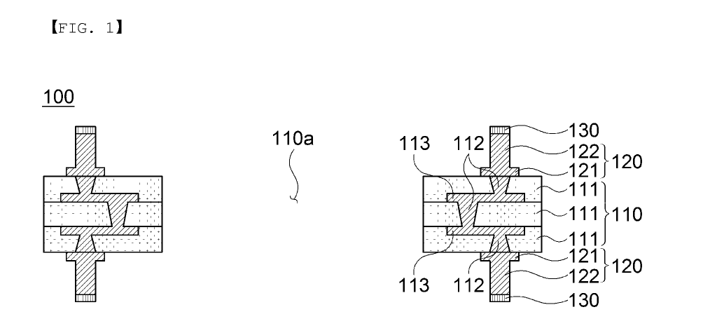

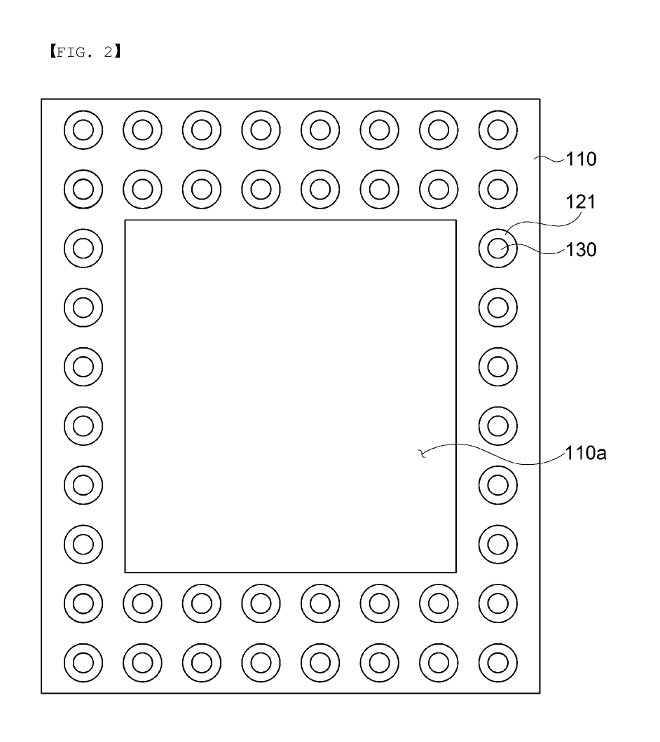

FIG. 1 is a cross-sectional view of an interposer according to an exemplary embodiment of the present invention, FIG. 2 is a plane view of the interposer according to the exemplary embodiment of the present invention, and FIG. 3 is a cross-sectional view of a semiconductor package using the interposer according to the exemplary embodiment of the present invention. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Referring to FIGS. 1 to 3, an interposer 100 according to an exemplary embodiment of the present invention has as a basic structure an interposer substrate 110 having an upper surface and a lower surface facing the upper surface and a connection electrode 120 disposed on at least any one of an upper surface and a lower surface of the interposer substrate 110.

The interposer substrate 110 may be configured of an insulating layer 111 which is made of a rigid dielectric material, such as fiber reinforced bismaleimide triazine (BT), FR-4, glass, and ceramic, or a flexible dielectric material, such as epoxy resin, phenol resin, urethane resin, silicon resin, and polyimide resin, as a base material.

The insulating layer 111 is stacked in a multi layer or otherwise may be configured in a single layer as illustrated in the drawing. FIG. 1 illustrates the interposer substrate 110 in which the insulating layers 111 of the flexible dielectric material are stacked on both surfaces of the insulating layer 111 made of the rigid dielectric material to stack a total of three insulating layers 111 in a thickness direction, in which the number of layers of the insulating layer 111 is not limited thereto but may be appropriately selected depending on a thickness of the required interposer 100.

The interposer substrate 110 is interlayer connected through the vias 112 through which the insulating layers 111 of each layer penetrate, such that one point on an upper portion of the interposer substrate 110 may be internally conducted to one point on a lower portion thereof. In this configuration, the vias 112 of each layer may have a stack via structure in which the vias are straightly connected to each other. Alternatively, the vias 112 may be formed at different positions for each layer and may also be connected to each other through metal wirings 113 formed on each insulating layer 111.

A center of the interposer substrate 110 may be provided with a cavity 110a which penetrates through the interposer substrate 110 in a thickness direction. Therefore, at the time of the configuration of the semiconductor package 200 (FIG. 3) using the interposer 100 according to the exemplary embodiment of the present invention, a semiconductor device 220 may be inserted into the cavity 110a, such that the semiconductor package 200 according to the exemplary embodiment of the present invention may be manufactured at a small chip scale package corresponding to a level of a chip size.

As described above, the remaining portion of the interposer substrate 110 on which the cavity 110a is formed may be provided with the connection electrode 120. The drawings illustrate the connection electrodes 120 are disposed on both of the upper and lower surfaces of the interposer substrate 110, but unlike the drawings, the connection electrode 120 may be disposed on any one of the upper and lower surfaces of the interposer substrate 110.

The connection electrode 120 may receive or transmit electrical signals from the outside, such that at the time of the configuration of the semiconductor package 200 using the interposer 100 according to the exemplary embodiment of the present invention, the connection electrode 120 may serve to electrically connect between the interposer substrate 110 and package substrates 210 which are disposed on the upper and lower portions of the interposer substrate 110. Therefore, the connection electrode 120 may be made of any one metal material of Ni, Al, Fe, Cu, Ti, Cr, Au, Ag, Pd, and Pt having excellent electrical conductivity and the number of connection electrodes 120 may be configured in plural, depending on the number of input/output terminals (I/O).

The connection electrode 120 may be configured to include a post part 122 having a pillar shape and a pad part 121 which is disposed between the post part 122 and the interposer substrate 110 to strengthen connection reliability between the vias 112, in which a height of the post part 122 may be controlled corresponding to the thickness of the semiconductor device 220 included in the cavity 110a at the time of the configuration of the semiconductor package 200. That is, the related art controls the thickness of the interposer depending on the number of layers of the insulating layer forming the interposer substrate, but the interposer 100 according to the exemplary embodiment of the present invention may be set to the required thickness by controlling a height of the connection electrode 120, in detail, the height of the post part 122 which is a component of the connection electrode 120.

Therefore, even though the interposer 100 having a large thickness is required due to the semiconductor device 220, the insulating layer is configured in a multi layer as in the related art, such that the required thickness of the interposer may be set by making only the post part 122 thick without needing to set the required thickness. As a result, the wasted material may be reduced due to the stacking of a multi-layer insulating layer, thereby saving the manufacturing cost and the number of processes of stacking the insulating layer is reduced, thereby shortening the manufacturing time and greatly increasing the production efficiency.

Further, when the number of layers of the insulating layer 111 forming the interposer substrate 110 is increased, a path of the electrical signals conducted through the vias 112 and the metal wirings 113 of each layer of the insulating layers 111 becomes long, such that it is highly likely to increase a signal loss and distortion. According to the exemplary embodiment of the present invention, since the number of layers of the insulating layer 111 may be reduced due to the use of the connection electrode 120 having the pillar shape, the signal path becomes short, such that the electrical characteristics may be improved.

Meanwhile, the upper surface of the post part 122 is further provided with a metal layer 130 made of Ni/Au (ENIG), Ni/Pd/Au (ENEPIG), or the like, such that at the time of the configuration of the semiconductor package 200 of FIG. 3, the bonding reliability with the package substrate 210 may be increased. Further, although not separately illustrated in the drawings, the surface of the connection electrode 120 may be provided with surface roughness to increase an adhesion.

Hereinafter, the connection electrode 120 having the structure and a method of manufacturing the interposer 100 including the same according to the exemplary embodiment of the present invention will be described.

FIGS. 4 to 10 are process diagrams sequentially illustrating the method of manufacturing an interposer according to the exemplary embodiment of the present invention. First, as illustrated in FIG. 4, the interposer substrate 110 which is formed by stacking the insulating layer 111 of one layer or more is prepared.

As the construction material of the insulating layer 111, the rigid dielectric material, such as fiber reinforced bismaleimide triazine (BT), FR-4, glass, and ceramic, or the flexible dielectric material, such as epoxy resin, phenol resin, urethane resin, silicon resin, and polyimide resin may be used.

At the time of stacking the insulating layer 111, the vias 112 and the metal wirings 113 for interlayer connection are formed on each insulating layer 111 by using a circuit forming process known to those skilled in the art, for example, a semi-additive process, a modified semi-additive process, a subtractive process, and the like and an outer layer of the interposer substrate 110 is provided with the pad part 121 which is bonded to the via 112.

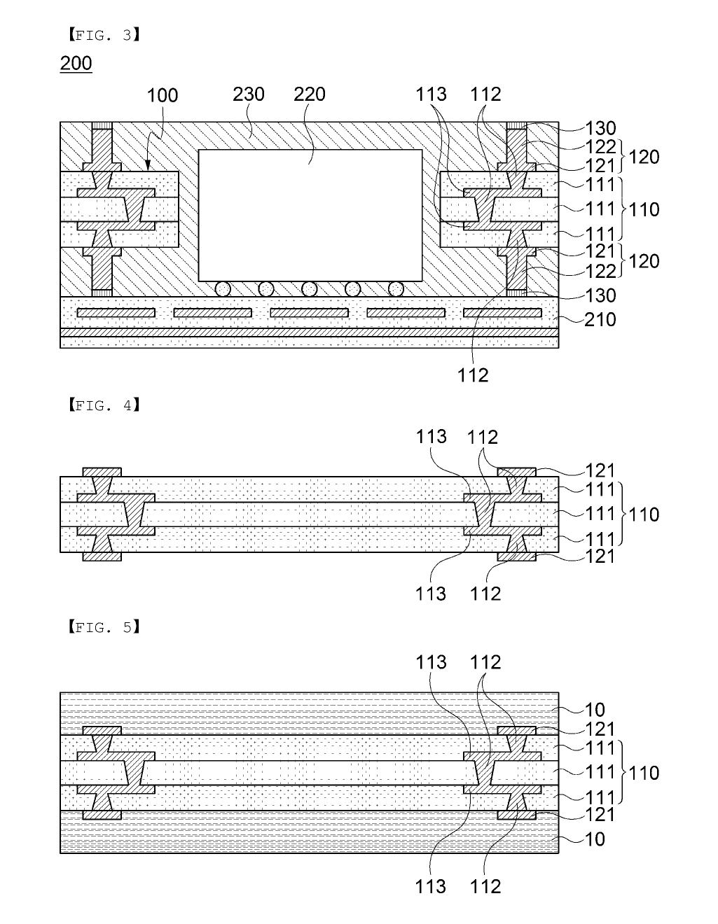

Next, as illustrated in FIG. 5, one surface or both surfaces of the interposer substrate 110 is subjected to a process of stacking a photo resist 10 having a predetermined height.

The photo resist 10 is a layer which is a base for forming the connection electrode 120, and the thickness of the photo resist 10 may be stacked at a height corresponding to the thickness of the connection electrode 120 and as the construction material thereof a photosensitive resin for forming the connection electrode 120 by a exposure and developing process is used.

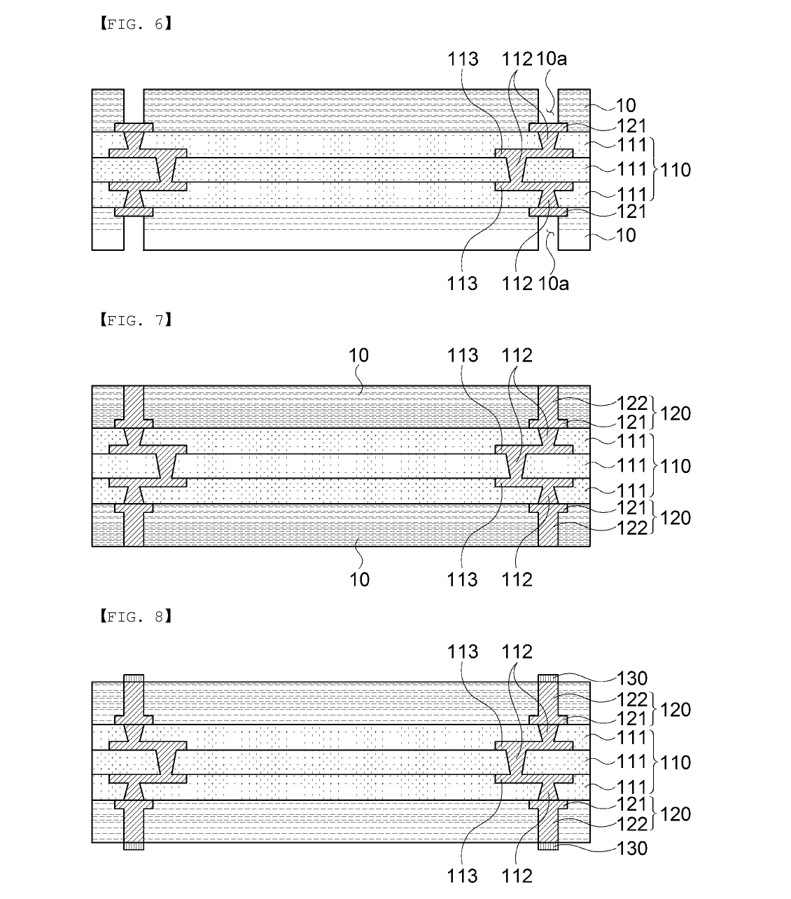

When the photo resist 10 is stacked as described above, as illustrated in FIG. 6, an opening 10a is machined at a predetermined position of the photo resist 10 and then an inside of the opening 10a is filled with a metal material (FIG. 7).

In detail, since the photo resist 10 is made of the photosensitive resin, when a photomask having a desired pattern, for example, an artwork film is stacked on the photo resist 10 and then the exposure process is performed, a portion of the photo resist 10 to which ultraviolet rays are irradiated is cured by starting a polymerization reaction by a photo initiator included therein and a portion to which ultraviolet rays are not irradiated, that is, a portion at which the post part 122 of the connection electrode 120 is formed is etched by a developing process of a developer later, thereby forming the opening 10a.

The so formed opening 10a may be filled with at least any one metal material selected from Ni, Al, Fe, Cu, Ti, Cr, Au, Ag, Pd, and Pt by using any one of electroless plating, electroplating, screen printing, sputtering, evaporation, inkjetting, and dispensing or a combination thereof.

As described above, when the opening 10a is filled with the metal materials and then the photo resist 10 is delaminated, the connection electrode 120 configured of the pad part 121 and the post part 122 formed thereon is completed and the surface of the photo resist may be further subjected to a process of polishing the surface of the photo resist 10 before the photo resist 10 is delaminated to planarize the height of the connection electrode 120. When the connection electrode 120, in detail, the height of the post part 122 is formed to be larger than the required value during the filling process, the value is set to the required value by the polishing process.

Further, after the polishing process, the upper surface of the post part 122 exposed to the surface of the photo resist 10 may be subjected to a process of forming the metal layer 130 made of Ni/Au (ENIG), Ni/Pd/Au (ENEPIG), or the like as the electroless surface treatment (FIG. 8). At the time of the configuration of the semiconductor package 200 by the metal layer 130, the bonding reliability between the interposer substrate 110 and the package substrate 210 may be greatly improved.

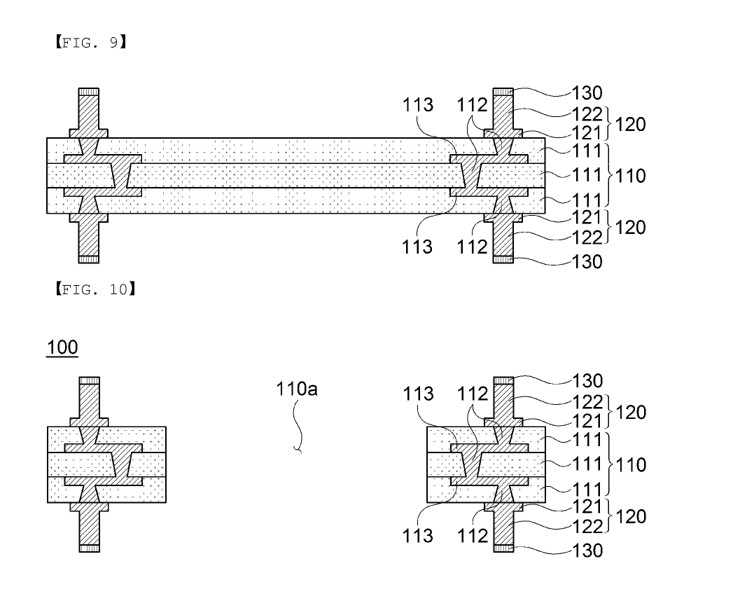

As described above, when the metal layer 130 is formed, the photo resist 10 is delaminated (FIG. 9) and then the cavity 110a is formed to penetrate through the center of the interposer substrate 110 in the thickness direction by a router or punching process, thereby finally completing the interposer 100 according to the exemplary embodiment of the present invention (FIG. 10).

In addition, in order to increase the adhesion of the connection electrode 120 at the time of the configuration of the semiconductor package 200, after the photo resist 10 is delaminated, the roughness of the surface of the connection electrode 120 may be further formed by performing a brown oxide process or an organic solderability preservative (OSP) process.

Hereinafter, a structure of the semiconductor package 200 using the interposer 100 according to the exemplary embodiment of the present invention depending on the process will be described in detail with reference to FIG. 3.

Referring to FIG. 3, the semiconductor package 200 using the interposer 100 according to the exemplary embodiment of the present invention includes the interposer substrate 110 and the package substrate 210, in which the package substrate 210 may be electrically connected to the interposer substrate 110 through the connection electrode 120.

Herein, the package substrate 210 includes a ceramic substrate, a PCB substrate, or the like, such as high temperature co-fired ceramic (HTCC) and low temperature co-fired ceramic (LTCC). The package substrate 210 is provided with circuit wirings depending on a previously designed pattern to configure signal lines, ground lines, and the like, of chip components.

One surface of the package substrate 210 may be provided with the semiconductor device 220 which is manufactured using silicon, silicon on insulator (SOI), silicon germanium, and the like. For example, multi-layer wirings, a plurality of transistors, a plurality of passive devices, and the like may be integrated in the semiconductor device 220 and FIG. 3 illustrates that the semiconductor device 220 is flip-chip bonded to the package substrate 210, but the exemplary embodiment of the present invention is not limited thereto and the semiconductor device 220 may be mounted on the package substrate 210 by various bonding methods, such as wire bonding.

In more detail, the semiconductor device 220 is mounted at a side at which the interposer substrate 110 is disposed and thus may be disposed to be inserted into the cavity 110a of the interposer substrate 110. Therefore, the thickness of the interposer 100 including the connection electrode 120 is formed to be larger than that of the mounted semiconductor device 220. In this case, the thickness of the interposer 100 may be controlled at the height of the post part 122.

A sealing material 230 may be filled up to the height of the interposer 100 so as to seal the semiconductor device 220 including the inside of the cavity 110a. The sealing material 230 may be, for example, an epoxy molding compound (EMC) material or an underfill material, but is not limited thereto and an encapsulant of various materials may be used.

Another package substrate on which the semiconductor device is mounted may be connected on the semiconductor package 200 (in detail, on the interposer substrate 110 at an opposite side to the package substrate 210) having the above-mentioned structure by the connection electrode 120, such that the semiconductor package 200 according to the exemplary embodiment of the present invention may also be manufactured to have a package-on-package (PoP) structure.

According to the exemplary embodiments of the present invention, since the thickness of the interposer is controlled at the height of the connection electrode having the pillar shape, the waste of the material due to the manufacturing of the insulating layer may be reduced, thereby saving the manufacturing costs and the process number for stacking the insulating layer is reduced, thereby shortening the manufacturing time and greatly increasing the production efficiency.

Further, the electrical signal is kept at the shortest distance while increasing the integration of the circuit, thereby greatly improving the electrical characteristics.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

1. An interposer, comprising:
an interposer substrate configured by stacking an insulating layer of one layer or more and interlayer connected through a via;
a cavity penetrating through a center of the interposer substrate in a thickness direction; and
a connection electrode having a post part which is disposed on at least one of an upper surface and a lower surface of the interposer substrate.

2. The interposer according to claim 1, wherein the connection electrode includes a pad part which is disposed between the post part and the interposer substrate.

3. The interposer according to claim 1, wherein a height of the post part is controlled corresponding to a thickness of the semiconductor device included in the cavity.

4. The interposer according to claim 1, wherein the connection electrode is configured in plural.

5. The interposer according to claim 1, wherein the upper surface of the post part is further provided with a metal layer.

6. The interposer according to claim 1, wherein a surface of the connection electrode is provided with roughness.

7. A semiconductor package, comprising:
a package substrate disposed on upper and lower portions of the interposer substrate according to claim 1 and electrically connected to the interposer substrate through the connection electrode;
a semiconductor device mounted on one surface of the package substrate and included in a cavity of the interposer substrate; and
a sealing material filled to seal the semiconductor device including an inside of the cavity.

8. A method of manufacturing an interposer, comprising:
preparing an interposer substrate configured by stacking an insulating layer of one layer or more and interlayer connected through a via;
stacking photo resists on one surface or both surfaces of the interposer substrate;
machining an opening at a position at which a connection electrode is formed in the photo resist and then filling an inside of the opening;
forming the connection electrode having a post part by delaminating the photo resist; and
forming a cavity to penetrate through a center of the interposer substrate in a thickness direction.

9. The method according to claim 8, wherein a thickness of the photo resist is stacked at a height corresponding to a thickness of the connection electrode.

10. The method according to claim 8, further comprising:
polishing a surface of the photo resist, after the forming of the connection electrode.

11. The method according to claim 8, further comprising:
prior to the forming of the connection electrode having a post part by delaminating the photo resist, forming a metal layer on an upper surface of the post part.

12. The method according to claim 8, further comprising:
after the forming of the connection electrode having a post part by delaminating the photo resist, forming roughness by surface treating the connection electrode.

13. A semiconductor package, comprising:
a package substrate disposed on upper and lower portions of the interposer substrate according to claim 2 and electrically connected to the interposer substrate through the connection electrode;
a semiconductor device mounted on one surface of the package substrate and included in a cavity of the interposer substrate; and
a sealing material filled to seal the semiconductor device including an inside of the cavity.

14. A semiconductor package, comprising:
a package substrate disposed on upper and lower portions of the interposer substrate according to claim 3 and electrically connected to the interposer substrate through the connection electrode;
a semiconductor device mounted on one surface of the package substrate and included in a cavity of the interposer substrate; and
a sealing material filled to seal the semiconductor device including an inside of the cavity.

15. A semiconductor package, comprising:
a package substrate disposed on upper and lower portions of the interposer substrate according to claim 4 and electrically connected to the interposer substrate through the connection electrode;
a semiconductor device mounted on one surface of the package substrate and included in a cavity of the interposer substrate; and
a sealing material filled to seal the semiconductor device including an inside of the cavity.

16. A semiconductor package, comprising:
a package substrate disposed on upper and lower portions of the interposer substrate according to claim 5 and electrically connected to the interposer substrate through the connection electrode;
a semiconductor device mounted on one surface of the package substrate and included in a cavity of the interposer substrate; and
a sealing material filled to seal the semiconductor device including an inside of the cavity.
